(19) United States
(12) Patent Application Publication
(10) Pub. No.: US 2007/0114056 A9
(43) Pub. Date: May 24, 2007

(54) Electrical isolation of PCBs gasketing using controlled depth drilling

(76) Inventors: Lloyd Cosman, Stittsville (CA); Farid Aziz, Kanata (CA); Craig Twardy, Gatineau (CA); Simon Shearman, Almonte (CA); Edmund Gillespie, Kanata (CA); Joan Wang, Ottawa (CA); Michael Tabatchnik, Ottawa (CA); Marko Nicolici, Ottawa (CA); Robert McDonald, Kanata (CA)

Correspondence Address: RIDOUT & MAYBEE;SUITE 2400, ONE QUEEN STREET EAST, TORONTO, ON, M5C3B1, CA

(21) Appl. No.: 10/863,998

(22) Filed: Jun. 9, 2004

(51) Int. Cl. H05K 1/09

(52) U.S. Cl. 174/257; 174/262

(57) ABSTRACT

A method of electrical isolation for printed circuit board gasketing is disclosed for enabling gasketing to overlay plated through holes without shorting out thereto. The method of electrical isolation for printed circuit board gasketing includes counterboring at a controlled width to a controlled depth those plated through holes underlying the gasketing. The method provides the advantage of being able to overlay gasketing on both surfaces of a printed circuit board mid-plane. The method of electrical isolation for printed circuit board gasketing is particularly useful for overcoming the additional material requirements and processing steps of electrical isolation known in the art.

### FIELD OF THE INVENTION

The present invention relates to electrical isolation of printed circuit board gasketing and is particularly concerned with provision of a relief bore as a means to attain electrical isolation.

### BACKGROUND OF THE INVENTION

The practice of using resilient gasketing for sealing apertures against electromagnetic radiation to preclude interference is well known in the art. A typical application for such gasketing is the sealing of a peripheral edge of an opening against which a panel is disposed.

As described in U.S. Pat. No. 6,723,916 issued Apr. 20, 2004 to Flaherty et al., for filling gaps within mating surfaces of housings and other EMI shielding structures, gaskets and other seals have been proposed. These gaskets and seals have been used for both maintaining electrical continuity across the structure, and for excluding from the interior of the structure such contaminates as moisture and dust. Such seals are bonded or mechanically attached to, or press-fit into, one of the mating surfaces, and function to close any interference gaps in order to establish a continuous electrically-conductive path across the gap. Furthermore, these seals must conform under an applied pressure to irregularities between the surfaces. Accordingly, seals intended for EMI shielding applications are specified to be of a construction which not only provides electrical surface conductivity even while under compression, but which also has a resiliency allowing the seals to conform to the size of the gap.

Application of gasketing has been further practiced with respect to the provision of electrical continuity from a backplane to a shielded replaceable enclosure. In some applications, component connectors are mounted to a mid/back-plane in a side-by-side arrangement. These component connectors are intended to accept electrical card-type electronic packs and the mid/back-plane facilitates complex electrical interconnections. The mid/back-plane typically has surface portions that are electrically-conductive. This electrically-conductive portion is sometimes known as a “conductive moat”. Each card-type electronic pack is shielded by an electrically-conductive clamshell that encompasses the card-type electronic pack and shields it from adjacent card-type electronic packs. Inevitably there is a gap between the clamshell and the electrically-conductive moat of the mid/back-plane. The gap is typically filled with an EMI gasket.

U.S. Pat. No. 5,483,423 discloses a gasket in which is mounted on the backplane of a cabinet, the backplane providing EMI shielding. The cabinet is adapted for the insertion of a plurality of electrical components, such as disk drives, tape drives, and power supplies, which themselves are mounted in a rigid frame member. The frame member includes EMI shielding for the components on five of their six sides. The sixth side is unshielded, due to the fact that it contains the electrical connector used to connect the component to the backplane of the cabinet, when the frame member is inserted in the cabinet. With the frame member providing shielding on five sides, and the backplane providing shielding for the sixth side, the gasket serves the purpose of establishing an electrical seal between the frame member and the backplane of the cabinet.

A disadvantage of the gasket assemblies disclosed in the prior art may be the need for either precluding or isolating plated through holes of the mid/back-plane from the conductive gasketing. Plated through holes in printed circuit boards are used for a variety of functions, chief among these as inter-layer connection points between signal and power traces within the mid/back-plane, commonly known as vias; as receiving apertures for component pins; as receiving apertures for connector pins using, for example press-fit technology; and as a means of connecting ground planes within the mid/back-plane to surface features. One example of such a surface feature would be the conductive moat to which the gasketing is attached or otherwise conductively disposed.

A problem arises when plated through holes for signals other than ground connections must be placed within the conductive moat areas. Normally, a plated through hole would have a conductive region or surface pad at the exit point of the plated hole to the surface of the printed circuit board. Under normal circuit board layout practices an insulating region is provided surrounding the surface pad, allowing the presence of plated through holes in, for example, a conductive moat area. The disposition of a conductive gasket onto the conductive moat acts as a conductive bridging element across the insulating region.

This bridging can be avoided by avoiding the presence of plated through holes within regions to which a conductive gasket is to be disposed. Alternatively, some form of insulation layer may be deployed between the gasket and those surface pads which are present, however this occurs additional material and assembly costs. In particular, in very dense circuitry applications the difficulties of interposing an isolation medium blocking conductive coupling to the surface pads while allowing conductive access to the conductive moat become progressively prohibitive.

In view of the foregoing, it would be desirable to provide a technique for gasketing which overcomes the above-described inadequacies and shortcomings by providing a mechanism which does allow good conductive access of a gasket to a conductive moat but does not preclude the presence of plated through holes in that same region.

### SUMMARY OF THE INVENTION

An object of the present invention is to provide an improved printed circuit board gasket assembly.

According to an aspect of the present invention there is provided a printed circuit board gasket assembly for a printed circuit board having a first plated through hole defined in the printed circuit board and a first resilient conductive gasket disposed on the printed circuit board wherein the resilient conductive gasket is positioned so as to overlay the plated through hole. Further, there is a relief bore defined at an end of the plated through hole adjacent to the resilient conductive gasket, the relief bore providing electrical insulation between the conductive portion of the plated through hole and the resilient conductive gasket.

Advantages of the present invention include providing for the presence of plated through holes in regions of the printed circuit board underlying the conductive gasket without electrical bridging occurring via the conductive gasket. Further, the present invention provides for avoiding bridging without the use of additional insulative materials having to be disposed on the surface pad of the plated through hole to isolate it from the conductive gasket.

Conveniently the printed circuit board may comprise a backplane, a motherboard, or a mid-plane. Also conveniently the resilient conductive gasket may comprise a panel having apertures let therein.

Advantageously, where the printed circuit board comprises a mid-plane, there may be a second plated through hole defined in the printed circuit board and a second resilient conductive gasket disposed on the printed circuit board on the side of the printed circuit board opposite to the first resilient conductive gasket, and overlaying the second plated through hole. There is also a relief bore defined at the end of the second plated through hole adjacent to the second resilient gasket. The relief bore provides electrical insulation between the conductive portion of the second plated through hole and the second resilient conductive gasket.

In accordance with another aspect of the present invention there is provided a method for isolating a conductive gasket from a plated through hole on a printed circuit board the method having the step of counterboring at a defined width to a controlled depth the plated through hole at an end of the plated through hole over which the conductive gasket is to be disposed. The combination of the defined width and controlled depth is chosen to be sufficient to provide an insulative spacing between the conductive gasket and the nearest remaining conductive portion of the plated through hole.

Conveniently the printed circuit board may comprise a backplane, a motherboard, or a mid-plane. Also conveniently the controlled depth may be a minimum of 0.010 inches from the counterbored surface of the printed circuit board, and the defined width may be a diameter about 0.010 inches greater than the as drilled diameter of the plated through hole.

In accordance with yet another aspect of the present invention, there is provided a printed circuit board gasket assembly for isolating a conductive gasket from a plated though hole over which it is disposed, the printed circuit board gasket assembly having a relief bore defined at an end of the plated through hole adjacent to the resilient gasket. The relief bore is dimensioned to provide electrical insulation between the resilient conductive gasket and the nearest remaining conductive portion of said plated through hole.

Conveniently the relief bore may have a cylindrical shape and an axis generally coaxial with the axis of the plated through hole. The depth of the cylindrical bore may conveniently be a minimum of 0.010 inches from the surface of the printed circuit board; and the diameter of the cylindrical bore about 0.010 inches greater than the drilled hole diameter of the plated through hole.

The present invention will now be described in more detail with reference to exemplary embodiments thereof as shown in the appended drawings. While the present invention is described below with reference to the preferred embodiments, it should be understood that the present invention is not limited thereto. Those of ordinary skill in the art having access to the teachings herein will recognize additional implementations, modifications, and embodiments which are within the scope of the present invention as disclosed and claimed herein.

### BRIEF DESCRIPTION OF THE DRAWINGS

The invention will be further understood from the following detailed description of embodiments of the invention and accompanying drawings in which:

FIG. 1 is a cross-sectional diagram of a printed circuit board with a plated through hole and resilient gasket according to the prior art.

FIG. 2A is a cross-sectional diagram of a printed circuit board with a plated through hole and bore according to an embodiment of the invention.

FIG. 2B is a cross-sectional diagram of the printed circuit board-of FIG. 2A with a resilient conductive gasket in place.

FIG. 3 is a perspective view of a mid-plane printed circuit board equipped with a gasket on each side according to an embodiment of the invention.

### DETAILED DESCRIPTION

The present invention will now be described in more detail with reference to exemplary embodiments thereof as shown in the appended drawings. It should be recognized that the diagrams are not intended to convey any indication of scale. While the present invention is described below including preferred embodiments, it should be understood that the present invention is not limited thereto. Those of ordinary skill in the art having access to the teachings herein will recognize additional implementations, modifications, and embodiments which are within the scope of the present invention as disclosed and claimed herein.

Certain terminology may be employed in the description to follow for convenience rather than for any limiting purpose. For example, the terms “top”, “bottom”, “forward”, “rearward”, “right”, “left”, “rightmost”, “leftmost”, “upper”, and “lower”designate directions in the drawings to which reference is made. Terminology of similar import other than the words specifically mentioned above likewise is to be considered as being used for purposes of convenience rather than in any limiting sense. In the description and figures to follow, corresponding characters are used to designate corresponding elements throughout the several views, with equivalent elements being referenced with prime or sequential alphanumeric designations where appropriate to assist understanding.

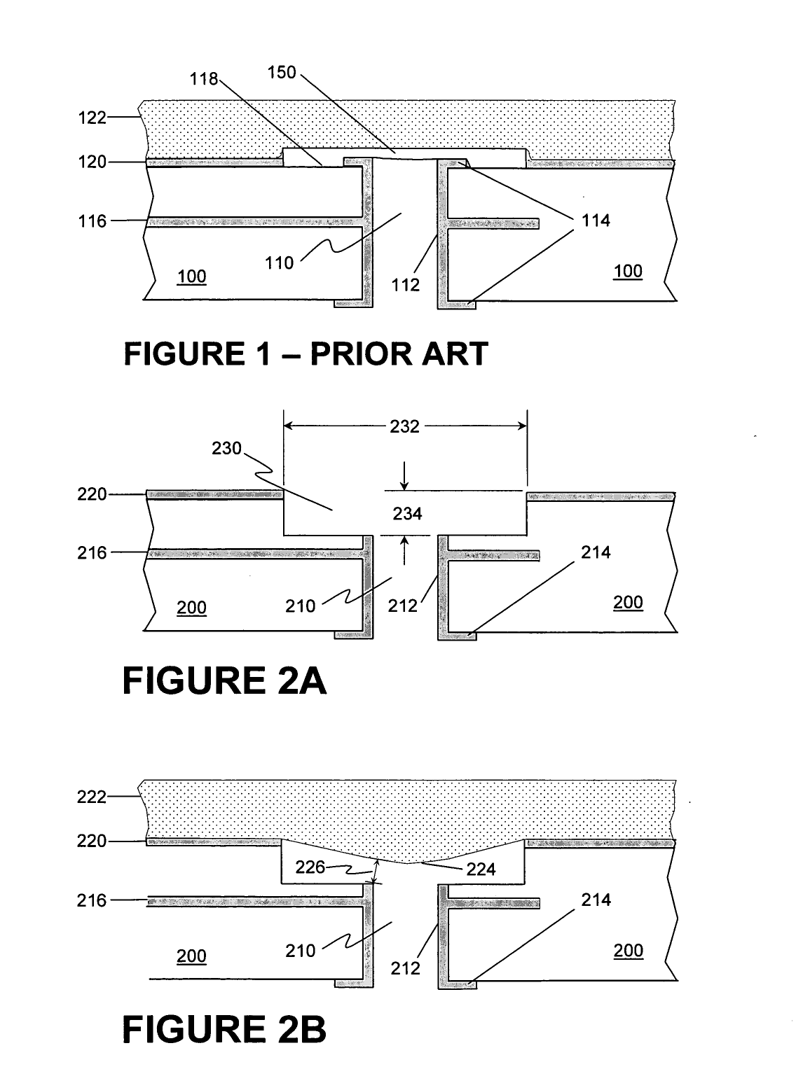

Referring to FIG. 1 there may be seen a cross-sectional view of a printed circuit board 100 having a plated through hole 110. Printed circuit board 100 may be a conventional technology copper-clad, fibreglass, multilayer printed circuit board, or alternatively may be any circuit board to which the advantages of the invention may pertain, for example alumina thick-film based technology. Typically, the application of printed circuit board 100 will be that of a back-plane or mid-plane, or a mother-board to which other assemblies are to be docked.

The plated through hole 110 has a conductive barrel 112 connected to surface pads 114 which are located at the surface of printed circuit board 100 and at the extreme ends of conductive barrel 112. Connected to conductive barrel 112 and lying on an inner layer within circuit board 100 is inner trace 116. Inner trace 116 may be a signal trace carrying digital or analog signals, or a power supply trace supplying current to electronic devices connected to printed circuit board 100. Alternatively, inner trace 116 may represent an internal ground plane, used for establishing a portion of a Faraday cage or to provide a low impedance reference plane for signals or power traces.

Plated through hole 110 may be used as a means of connecting traces between different internal layers, or between internal layers and the surface layers, or between traces on one layer and a ground or power plane on a different layer. Plated through holes used to carry signals from layer to layer are generally known as vias in the art. Plated through holes may also be used as a component lead mounting points for through-hole components, or as the receptacle and connection point for connectors, for example those using press-fit technology. Although a single inner trace 116 has been illustrated, it is to be understood that a given plated through hole may have a plurality of traces connected to it, traces running on either internal or external layers of printed circuit board 100.

The surface pad 114 of plated through hole 110 has a insulative space 118 surrounding it. This insulative space 118 is representative of the area surrounding surface pad 114 where the conductive copper layer has been removed during the printed circuit board manufacturing process. Insulative space 118 separates surface pad 114 from conductive region 120.

Disposed over the printed circuit board is resilient conductive gasket 122. Conductive region 120 represents the region of the printed circuit board to which a conductive connection to gasket 122 is desired. Typically such a region is grounded or otherwise connected to equipment members so as to form part of a Faraday cage.

In order to isolate plated through hole 110 from gasket 122, an insulative material 150 may be disposed over surface pad 114. This isolation is necessary to prevent gasket 122 from conductively connecting surface pad 114 to conductive region 120. The necessity for insulative material 150 imposes both a material cost for the insulative material and a manufacturing cost because of the necessity to carefully register the insulative material over the surface pad 114 and plated through hole 110. It is also apparent from inspection that a blanket coating of insulative material 150 would not serve, as although it would be simple to apply, such a blanket application would block conductive connection between conductive region 120 and gasket 122.

Referring now to FIG. 2A, there may be seen a cross-sectional diagram of a printed circuit board 200 with a plated through hole 210 according to an embodiment of the invention. Plated through hole 210 has a conductive barrel 212 connected to a surface pad 214 which is located at the surface of printed circuit board 200 and at the one end of conductive barrel 212. Connected to conductive barrel 212 and lying on an inner layer within circuit board 200 is inner trace 216. On the top surface of printed circuit board 200 may be seen conductive region 220 which represents the region of the printed circuit board for which a conductive connection to a gasket can be established.

Defined at the end of plated through hole 210 is a bore 230 having a width 232 and depth 234. The term bore is used here in the sense of a cavity from which material has been removed. Typically bore 230 will be formed via a counterbore operation on printed circuit board 200 at some point after lamination and final copper etching, however it is contemplated other approaches to establishing the presence of bore 230 may be used such as laser milling, or boring prior to plating accompanied by subsequent etching of copper from within the bore, for example. For the purposes of the invention herein disclosed the manufacturing method used to define the bore is not essential to the operation of the invention insofar as the manufacturing method used is adequate to establishing an adequate bore.

Bore 230 has a width 232 and depth 234 which are dimensioned to provide sufficient distance through air and across the interior surface of bore 230 to insulate barrel 212 from conductive region 220. A typical size for width 232 would be the drilled hole size for plated through hole 210 plus 0.010 inches. In the case where plated through hole 210 is that of a signal via, the standard drilled plated through hole size would be 0.026 inches, and therefore width 232 would be 0.036 inches. In the case where plated through hole 210 is that of a power trace via, the standard drilled hole size would be 0.033 inches, and therefore width 232 would be 0.043 inches. A typical size for bore depth 234 would be a minimum of 0.010 inches. Conveniently, the bore 230 may be cylindrical in shape, with the cylindrical axis coaxial within manufacturing tolerances, to the central axis of the plated through hole 210.

Referring now to FIG. 2B, there may be seen a cross-sectional diagram of the printed circuit board 200 of FIG. 2A with a resilient conductive gasket 222 in place over plated through hole 210. On the top surface of printed circuit board 200 conductive region 220 is in conductive connection to resilient conductive gasket 222. As per normal practise, this is established, for example, by a conductive adhesive layer or by contact pressure established by a mechanical fastener (not shown).

Resilient conductive gasket 222 will produce a bulge 224 which will have a size proportional to gasket 222 resiliency, bore width 232, and pressure disposed upon gasket 222 by overlaying mechanical assemblies, and perhaps other factors such as local gasket temperature. Closest approach distance 226 represents the minimum distance which manifests between any portion of bulge 224 and any conductive portion of plated through hole 210, which in general will be some portion of the barrel 212.

Bore width 232 and depth 234 determinations must necessarily take this closest approach distance 226 into account. For example should unusually resilient gasket material be utilized, or should excessive pressures and temperatures be developed at the gasket, a greater bulge 224 may result. Alternatively, regulatory or customer requirements may necessitate a particular guaranteed minimum distance between a ground plane and a signalling trace connected to telecommunications lines. Calculation of bulge 224 and resulting closest approach distance 226 may readily be done by methods known to those skilled in the art when given the mechanical characteristics of a particular resilient gasket material from the gasket manufacturer.

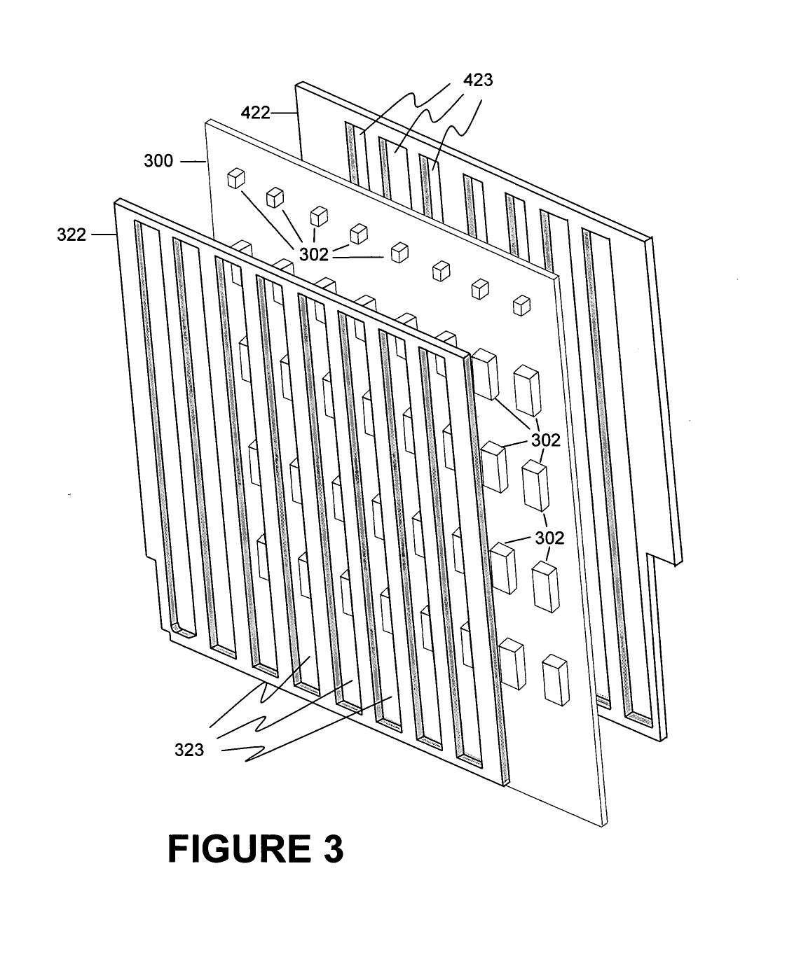

Referring now to FIG. 3, there may be seen a perspective view of an application of an embodiment of the invention in a mid-plane printed circuit board equipped with a gasket on each side. Circuit board mid-plane 300 contains a plurality of connector pin assemblies 302. Intended for siting in an electrical equipment shelf, mid-plane 300 resides in the middle of the shelf allowing equipment modules to be inserted to the shelf from both sides.

Although not visible in FIG. 3, it is to be understood that there exists a further plurality of connector pin assemblies similar to connector pin assemblies 302 on the opposite side of mid-plane 300. These opposite side connector pin assemblies are disposed offset to the plurality of connector pin assemblies 302 to preclude the connector pins from connectors on one side from electrically shorting to connector pins on the opposite side. Connector pin assemblies 302 in this embodiment, comprise a plurality of pins press-fit into plated through holes in mid-plane 300.

Resilient conductive gasket panel 322 has apertures 323 let into it. The apertures are sized so as to provide openings for the connector pin assemblies 302. On the opposite side of mid-plane 300, resilient conductive gasket panel 422 has apertures 423 let into it. The apertures are sized so as to provide openings for the corresponding connector pin assemblies on that side of mid-plane 300. The use of a gasket panel simplifies the installation of the resilient conductive gasketing as the gasketing may be applied in a single operation. The gasket panels 322 and 422 will be disposed onto their respective sides of mid-plane 300 and held in place via conductive adhesive.

Due to the requirements of maximum circuit density, the mid-plane 300 is sized so as to maximize the number of connector pin assemblies on each side. The resulting geometry has resilient gasket panel 422 overlaying the plated through holes for connector pin assemblies 302, and likewise, resilient gasket panel 322 overlays the plated through holes for the connector pin assemblies on the opposite side of mid-plane 300.

As described in the preceding description, by providing an appropriately dimensioned bore for each of the plated through holes associated with connector pin assemblies 302 and those of the opposite side which lie immediately under resilient conductive gasket panels 322 and 422, the gasket panels do not short-circuit the connector pin assemblies. As is clear, the same bores would be applied to any other plated through holes underlying conductive gasket panels 322 and 422 which are present for reasons other than the connector pin assemblies. Provision of the bores allows for a enhanced gasketing connectivity to a ground region atop the mid-plane 300, and allow increased connector density achieved with a lower final assembly cost due to the absence of insulative materials which would otherwise be needed to block gasket to connector pin plated through hole shorting.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims.

What is claimed is:

1. A printed circuit board gasket assembly comprising:
a printed circuit board;
a first plated through hole defined in said printed circuit board;
a first resilient conductive gasket disposed on said printed circuit board wherein said first resilient conductive gasket is positioned so as to overlay said first plated through hole; and
a first relief bore defined at an end of said first plated through hole adjacent to said resilient gasket, said relief bore providing electrical insulation between the conductive portion of said first plated through hole and said resilient conductive gasket.

2. A printed circuit board gasket assembly as claimed in claim 1 wherein said printed circuit board comprises a backplane.

3. A printed circuit board gasket assembly as claimed in claim 2 wherein said first resilient conductive gasket comprises a panel having apertures let therein.

4. A printed circuit board gasket assembly as claimed in claim 1 wherein said printed circuit board comprises a motherboard.

5. A printed circuit board gasket assembly as claimed in claim 1 further comprising:
a second plated through hole defined in said printed circuit board;
a second resilient conductive gasket disposed on said printed circuit board wherein said second resilient conductive gasket is positioned on the side of said printed circuit board opposite to said first resilient conductive gasket, so as to overlay said second plated through hole; and
a second relief bore defined at an end of said second plated through hole adjacent to said second resilient conductive gasket, said relief bore providing electrical insulation between the conductive portion of said second plated through hole and said second resilient conductive gasket.

6. A printed circuit board gasket assembly as claimed in claim 5 wherein said printed circuit board comprises a mid-plane.

7. A printed circuit board gasket assembly as claimed in claim 6 wherein at least one of said first resilient conductive gasket and said second conductive gasket comprises a panel having apertures let therein.

8. A method for isolating a conductive gasket from a plated through hole on a printed circuit board comprising:
counterboring at a defined width to a controlled depth the plated through hole at an end of the plated through hole over which the conductive gasket is to be disposed, wherein the combination of the defined width and controlled depth is sufficient to provide an insulative spacing between the conductive gasket and the nearest remaining conductive portion of the plated through hole.

9. A method for isolating a conductive gasket as claimed in claim 8 wherein said printed circuit board comprises a backplane.

10. A method for isolating a conductive gasket as claimed in claim 8 wherein said printed circuit board comprises a motherboard.

11. A method for isolating a conductive gasket as claimed in claim 8 wherein said printed circuit board comprises a mid-plane.

12. A method for isolating a conductive gasket as claimed in claim 8 wherein said controlled depth is a minimum of 0.010 inches from the counterbored surface.

13. A method for isolating a conductive gasket as claimed in claim 8 wherein said defined width is about a diameter 0.010 inches greater than the as drilled diameter of said plated through hole.

14. A printed circuit board gasket assembly for isolating a conductive gasket from a plated though hole over which it is disposed, said printed circuit board gasket assembly comprising:
a relief bore defined at an end of the plated through hole adjacent to the resilient gasket, said relief bore dimensioned to provide electrical insulation between the resilient conductive gasket and the nearest remaining conductive portion of said plated through hole.

15. A printed circuit board gasket assembly as claimed in claim 14 wherein said relief bore comprises:
a cylindrical shape;
an axis of said cylindrical bore generally coaxial with the axis of said plated through hole;
a depth of said cylindrical bore of a minimum of 0.010 inches from the surface of said printed circuit board;
and
a diameter of said cylindrical bore about 0.010 inches greater than the drilled hole diameter of said plated through hole.

16. A printed circuit board gasket assembly as claimed in claim 15 wherein said printed circuit board comprises one of the group of backplane, motherboard, and mid-plane.
